(19) United States
(12) Patent Application Publication
(10) Pub. No.: US 2024/0355661 A1
(43) Pub. Date: Oct. 24, 2024

(54) PLACEMENT BASE

(71) Applicant: DAIFUKU CO., LTD., Osaka (JP)

(72) Inventor: Zheguang DONG, Hino-cho (JP)

(73) Assignee: DAIFUKU CO., LTD., Osaka (JP)

(21) Appl. No.: 18/581,869

(22) Filed: Feb. 20, 2024

(30) Foreign Application Priority Data
Apr. 20, 2023 (JP) 2023-069579

(51) Int. Cl. H01L 21/677

(52) U.S. Cl. CPC H01L 21/67775

(57) ABSTRACT

Achieved is a placement base that can suppress generation of particles during positioning even if a load of a storage container is increased. The placement base includes positioning pins protruding upward from a top surface of the placement base on which top surface a storage container is to be placed; and buffer bodies, each positioning pin being provided on the top surface of the placement base, to be engaged with each positioning grooves, each buffer body being provided for each positioning pins, the buffer bodies having upper ends that are able to be pressed downward and are configured to be biased upward when the upper ends are pressed down, the buffer bodies being, while the upper ends are not being pressed down, located at a height at which the buffer bodies come contact with, before the positioning pins, with the bottom surface of the storage container to be placed.

This Nonprovisional application claims priority under 35 U.S.C. § 119 on Patent Application No. 2023-069579 filed in Japan on Apr. 20, 2023, the entire contents of which are hereby incorporated by reference.

### TECHNICAL FIELD

The present invention relates to a placement base on which a storage container is to be placed.

### BACKGROUND ART

Conventionally, techniques of providing positioning mechanisms have been used in order to precisely place storage for semiconductor wafers or the like conveyed. For example, Patent Literature 1 discloses a technique in which a bottom-surface depression provided on a bottom surface of a body part of a container and a positioning member that is elastically deformable in an up-and-down direction and that is included in a support member are engaged with each other so as to place the container at an appropriate position in a horizontal direction.

### CITATION LIST

### Patent Literature

### Patent Literature 1

Japanese Patent Application Publication Tokukai No. 2016-94264

### SUMMARY OF INVENTION

### Technical Problem

However, in such a conventional technique, in a case where a load of the container is increased, wear may occur between the positioning member and the container in a short period, resulting in generation of particles. The generation of particles poses a problem when products that require high cleanliness level are handled.

It is an object of an aspect of the present invention to achieve a placement base that can suppress generation of particles during positioning even in a case where a load of a storage container is increased.

### Solution to Problem

In order to solve the foregoing problem, a placement base in accordance with an aspect of the present invention is a placement base on which a storage container provided with a plurality of positioning grooves on a bottom surface of the storage container is to be placed, the placement base including: a plurality of positioning pins protruding upward from a top surface of the placement base, on which top surface the storage container is to be placed; and a plurality of buffer bodies protruding upward from the top surface of the placement base, each of the plurality of positioning pins being provided on the top surface of the placement base in a manner so as to be engaged with a corresponding one of the plurality of positioning grooves, at least one of the plurality of buffer bodies being provided for each of the plurality of positioning pins, the plurality of the buffer bodies having upper ends that are able to be pressed downward and that are configured to be biased upward when the upper ends are pressed down, the plurality of buffer bodies, while the upper ends are not being pressed downward, being located at a height at which the plurality of buffer bodies come into contact, before the plurality of positioning pins, with the bottom surface of the storage container to be placed.

### ADVANTAGEOUS EFFECTS OF INVENTION

According to an aspect of the present invention, it is possible to achieve a placement base that can suppress generation of particles during positioning even in a case where a load of a storage container is increased.

### BRIEF DESCRIPTION OF DRAWINGS

FIG. 1 is a cross-sectional view illustrating a placement base in accordance with Embodiment 1 of the present invention and a storage container.

FIG. 2 is a view illustrating a bottom surface of the storage container.

FIG. 3 is a view illustrating each of buffer bodies and each of positioning pins during placement of the storage container on the placement base.

FIG. 4 is a cross-sectional view illustrating a placement base in accordance with Embodiment 2 of the present invention and a storage container.

FIG. 5 is a view illustrating a bottom surface of the storage container.

FIG. 6 is a view illustrating each of buffer bodies and each of positioning pins during placement of the storage container on the placement base.

### DESCRIPTION OF EMBODIMENTS

Embodiment 1

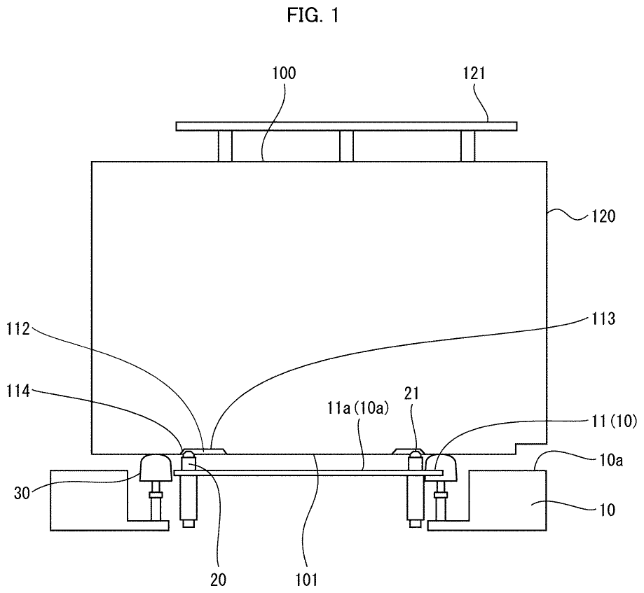

The following description will discuss an embodiment of the present invention in detail. Note, however, that the following description discusses one example of a placement base 10 in accordance with the present invention, and the technical scope of the present invention is not limited to the examples in the drawings. The following description assumes that, relative to a container body 120 in FIG. 1, a gripped part 121 side is an upward direction, and a bottom surface 101 side is a downward direction.

### Overview of Placement Base

In order to precisely place a storage container 100 conveyed, the storage container 100 and the placement base 10 are provided with positioning mechanisms. The positioning mechanisms function with use of (i) positioning grooves 112 provided on a bottom surface 101 of the storage container 100 and (ii) positioning pins 20 provided to the placement base 10.

FIG. 1 is a cross-sectional view illustrating the placement base 10 in accordance with Embodiment 1 of the present invention and the storage container 100. When the storage container 100 is lowered downward toward the placement base 10, inclination parts 114 of the positioning grooves 112 in the positioning mechanisms come into contact with tips of the positioning pins 20 in the positioning mechanisms. The storage container 100 is further lowered in this state so as to guide the positioning pins 20 to flat parts 113 of the positioning grooves 112. Accordingly, the storage container 100 is guided to a placement position.

In the present embodiment, as illustrated in FIG. 1, the placement base 10 is provided with buffer bodies 30 for the respective positioning pins 20. The buffer bodies 30 have upper ends each of which can be pressed downward and is configured to be biased upward when the upper end is pressed down. The buffer bodies 30 are, while the upper ends are not being pressed downward, located at a height at which the buffer bodies 30 come into contact, before the positioning pins 20, with the bottom surface 101 of the storage container 100 to be placed.

This allows the buffer bodies 30 to bear or absorb a load or swing of the storage container 100 which occurs when the storage container 100 is placed on the placement base 10. Therefore, even in a case where the load of the storage container 100 is large, it is possible to suppress the occurrence of wear between the positioning pins 20 and the storage container 100. This makes it possible to suppress the generation of particles during positioning even in a case where the load of the storage container 100 is increased.

### Storage Container

The storage container 100 is a conveyance container used when products are conveyed. The storage container 100 is, for example, a front opening unified pod (FOUP) or a front open shipping box (FOSB). The storage container 100 includes a container body 120 and a gripped part 121. The container body 120 is a housing having a substantially cuboid shape and, although not illustrated, stores products that require high cleanliness level, e.g., semiconductor wafers or the like. The storage container 100 is gripped at the gripped part 121 thereof and is conveyed from an appropriate position to a position above the placement base 10. The storage container 100 is then lowered and is placed on the placement base 10.

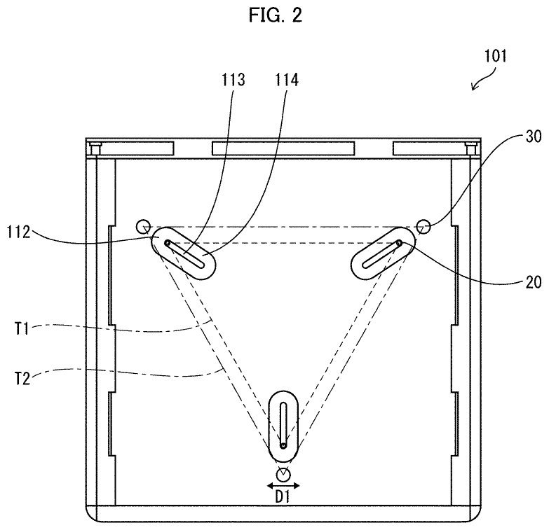

The bottom surface 101 of the storage container is provided with the plurality of positioning grooves 112 as part of the bottom surface 101. FIG. 2 is a view illustrating the bottom surface 101 of the storage container 100. Note that FIG. 2 also illustrates, with solid lines, positions at which the positioning pins 20 and the buffer bodies 30 abut on the bottom surface 101. As illustrated in FIG. 2, the three positioning grooves 112 are provided radially from a substantially center part of the bottom surface 101 toward the outer periphery of the bottom surface 101. Each of the positioning grooves 112 is shaped so as to be depressed upward. The positioning groove 112 has a tapered shape such that the positioning groove 112 becomes thinner toward an upper position. Accordingly, the positioning groove 112 has the inclination part 114.

Further, the center part of the positioning groove 112 in a width direction D1 of the positioning groove 112 forms the flat part 113 parallel to a main surface of the bottom surface 101 of the storage container 100. Here, the main surface of the bottom surface 101 refers to the entire bottom surface 101 in a case where the bottom surface 101 is regarded as one flat surface. That is, being parallel to the main surface of the bottom surface 101 means being parallel to a direction along the entire bottom surface 101 that is regarded as one flat surface. The positioning grooves 112 are provided so that, when the storage container 100 is placed on the placement base 10, the positioning pins 20 provided to the placement base 10 are to be engaged with the positioning grooves 112 from below.

### Placement Base

On the placement base 10, the storage container 100 is to be placed. The placement base 10 includes the positioning pins 20 and the buffer bodies 30.

In the placement base 10, a part of a top surface 10a of the placement base 10 is a top surface 11a of a plate 11. The plate 11 may be supported by a part of the placement base 10. Further, the height of the plate 11 may be adjustable in an up-and-down direction, and a position of the plate 11 may be adjustable in a horizontal direction.

### Positioning Pins

The plurality of positioning pins 20 are provided and protrude upward from the top surface 10a on which the storage container 100 is to be placed. Each of the plurality of positioning pins 20 is provided on the top surface 10a in a manner so as to be engaged with each of the positioning grooves 112. In addition, as illustrated in FIG. 2, each of the positioning pins 20 is provided on the top surface 10a so that, when the storage container 100 is placed on the placement base 10, the positioning pin 20 is to be located at an end part of the flat part 113 of the positioning groove 112, the end part being located on an outer periphery side of the bottom surface 101.

The positioning pins 20 have substantially cylindrical shapes and have upper end parts provided with flat parts 21 substantially parallel to a horizontal direction. In a case where the storage container 100 to be placed on the placement base 10 is shifted in the horizontal direction relative to the placement position, the positioning pins 20 are guided to the flat parts 113 of the positioning grooves 112 so as to guide the storage container 100 to an appropriate placement position.

The positioning pins 20 are fixed to the plate 11. For example, base portions for the positioning pins 20 are fixed to the placement base 10 and have threaded tips, and the positioning pins 20 are screwed to the base portions so as to be fixed to the placement base 10.

### Buffer bodies

The plurality of buffer bodies 30 are provided and protrude upward from the top surface 10a. In addition, the buffer bodies 30 are provided for the respective positioning pins 20. In the present embodiment, the buffer bodies 30 are provided for the respective positioning pins 20. The buffer bodies 30 are not limited to the above configuration. It is alternatively possible that the plurality of buffer bodies 30 are provided for each of the positioning pins 20.

The buffer bodies 30 each have an upper end which can be pressed downward and is configured to be biased upward when the upper end is pressed down. In addition, the buffer bodies 30 are, while the upper ends are not being pressed downward, located at a height at which the buffer bodies 30 come into contact, before the positioning pins 20, with the bottom surface 101 of the storage container 100 to be placed.

This causes, in placement of the storage container 100 on the placement base 10, the buffer bodies 30 to come into contact with the bottom surface 101 of the storage container 100 before the positioning pins 20 come into contact with the bottom surface 101 of the storage container 100. Therefore, the buffer bodies 30 can bear a load of the storage container 100 which occurs when the storage container 100 is placed on the placement base 10. This makes it possible to suppress the occurrence of wear between the positioning pins 20 and the storage container 100 even in a case where the load of the storage container 100 is large. Thus, it is possible to suppress the generation of particles during positioning even in a case where the load of the storage container 100 is increased.

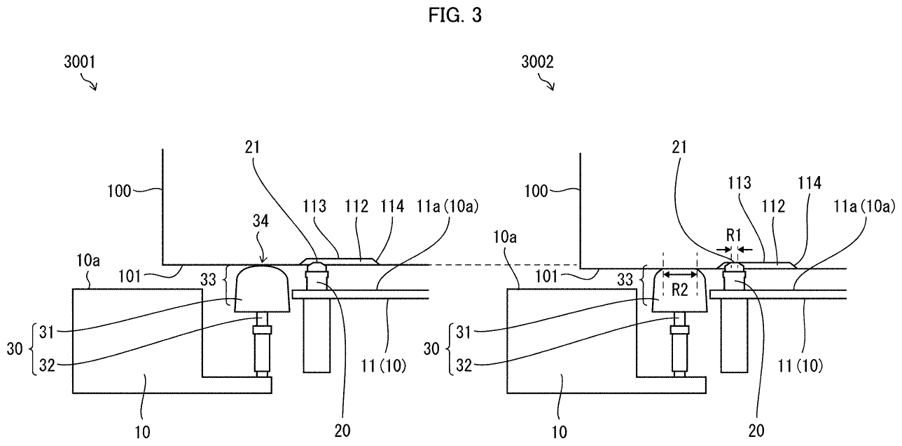

FIG. 3 is a view illustrating each of the buffer bodies 30 and each of the positioning pins 20 during placement of the storage container 100 on the placement base 10. The reference numeral 3001 of FIG. 3 indicates the buffer body 30 and the positioning pin 20 at the time point of a start of the contact of the buffer body 30 with the bottom surface 101 of the storage container 100. The reference numeral 3002 of FIG. 3 indicates the buffer body 30 and the positioning pin 20 in a state where the storage container 100 is placed on the placement base 10. As illustrated in FIG. 3, the buffer body 30 has an elastic part 31 made of elastic material, and the elastic part 31 includes an upper end part 33 of the buffer body 30. Examples of the elastic material include rubber.

As illustrated in the reference numeral 3001 of FIG. 3, even when the storage container 100 is lowered from a position above the placement base 10, and the buffer body 30 comes into contact with the bottom surface 101 of the storage container 100, the positioning pin 20 does not come into contact with the bottom surface 101 (positioning groove 112). The storage container 100 is further lowered in this state, and then the upper end part 33 of the buffer body 30 is pressed downward and the positioning pin 20 comes into contact with the flat part 113, as illustrated in the reference numeral 3002 of FIG. 3, so that the storage container 100 becomes stationary. As a result, the storage container 100 is placed on the placement base 10.

As described above, the upper end parts 33 of the buffer bodies 30 are constituted by the elastic parts 31. When the storage container 100 is placed on the placement base 10, the elastic parts 31 are deformed. This makes it possible to place the storage container 100 on the placement base 10 with use of the positioning pins 20 while causing the buffer bodies 30 to bear the load of the storage container 100.

The buffer bodies 30 are provided on the top surface 10a so as to correspond, when the storage container 100 is placed on the placement base 10, to positions on the bottom surface 101 of the storage container 100, other than the positions of the positioning grooves 112.

The buffer bodies 30 are provided on the top surface 10a so as to correspond to positions other than the positions of the positioning grooves 112, as described above, and thus have no effect on the positioning function for the storage container 100. In addition, it is possible to determine the size of the buffer body 30 irrespective of the size of the positioning groove 112. For example, increasing an area in which the buffer bodies 30 come into contact with the bottom surface 101 when the storage container 100 is placed on the placement base 10 makes it possible to increase a load of the storage container 100 which the buffer bodies 30 bear. This makes it possible to handle the storage container 100 having a larger load.

The upper end part 33 of the buffer body 30 has a round shape in which the uppermost end of the upper end part 33 is a center part 34 of the buffer body 30. When the storage container 100 is lowered toward the placement base 10, the storage container 100 cannot, in some cases, be lowered in a completely horizontal state. If the upper end parts 33 of the buffer bodies 30 are flat so as to be substantially parallel to a horizontal direction, the buffer bodies 30 are provided with corners, and the corners will wear out. Therefore, each of the buffer bodies 30 has the upper end part 33 having a round shape and thus evenly receives a load of the storage container 100. This can prevent, for example, each of the buffer bodies 30 from wearing out unevenly.

Each of the buffer bodies 30 further includes, below the upper end part 33 thereof, a length adjusting mechanism 32 that adjusts a length by which the buffer body 30 protrudes upward from the top surface 10a. This causes the length of the buffer bodies 30 in the up-and-down direction to be adjustable. Thus, it is possible to adjust a proportion of the load of the storage container 100 which the buffer bodies 30 bear. Further, even if the elastic parts 31 are deformed due to use of the buffer bodies 30, adjusting the lengths of the buffer bodies 30 enables long-term use of the buffer bodies 30. The length adjusting mechanism 32 may be constituted by, for example, a screw.

Each of the buffer bodies 30 has a columnar shape with a diameter larger than that of each of the positioning pins 20. The following provides a specific description. The buffer body 30 has a substantially cylindrical shape. As illustrated in the reference numeral 3002 of FIG. 3, in a state in which the storage container 100 is placed on the placement base 10, the flat part 21 of the upper end of the positioning pin 20 comes into contact with the flat part 113 of the positioning groove 112. Further, the upper end part 33 of the buffer body 30, in a deformed state, comes into contact with the bottom surface 101 of the storage container 100. Assuming that the diameter of the flat part 21 of the upper end of the positioning pin 20 is “R1” and that the diameter of the contact part between the buffer body 30 deformed and the bottom surface 101 of the storage container 100 is “R2”, R2 is larger than R1.

This makes it possible to cause the buffer bodies 30 to bear a larger proportion of the load of the storage container 100 than that which the positioning pins 20 bear. Therefore, it is possible to further suppress the occurrence of wear between the positioning pins 20 and the storage container 100.

On the top surface 10a, the positioning pins 20 are provided at positions that correspond, when the storage container 100 is placed on the placement base 10, to respective vertices of a first imaginary triangle T1 (see FIG. 2). In addition, on the top surface 10a, the buffer bodies 30 are provided at positions that correspond, when the storage container 100 is placed on the placement base 10, to respective vertices of a second imaginary triangle T2 (see FIG. 2) which encompasses the first imaginary triangle T1 and which is made by enlarging the first imaginary triangle T1.

In other words, the buffer bodies 30 are provided closer to the outer periphery sides of the bottom surface 101 than the positioning grooves 112 are, on the radial lines passing the positioning grooves 112 from a substantially center part of the bottom surface 101. The buffer bodies 30 are preferably adjacent to the positioning pins 20. This makes it possible to provide the buffer bodies 30 evenly on the bottom surface 101 of the storage container 100. Thus, it is possible to suppress the occurrence of wear between the positioning pins 20 and the storage container 100.

The positions at which the buffer bodies 30 are provided on the top surface 10a are not limited to the above-described ones. For example, the single buffer body 30 may be provided, on the top surface 10a, at a position corresponding to a substantially center part of the first imaginary triangle T1, provided that the single buffer body 30 and the positioning pins 20 can evenly share the load of the storage container 100.

The buffer bodies 30 are fixed to portions of the placement base 10, other than where the plate 11 is. Disposing the buffer bodies 30 at portions in the placement base 10, other than where the plate 11 is makes it possible to cause the buffer bodies 30 to be strongly held. This allows the buffer bodies 30 to bear a larger load.

### Embodiment 2

The following description will discuss another embodiment of the present invention. For convenience of description, a member having a function identical to that of a member discussed in Embodiment 1 above is given an identical reference sign, and a description thereof is omitted.

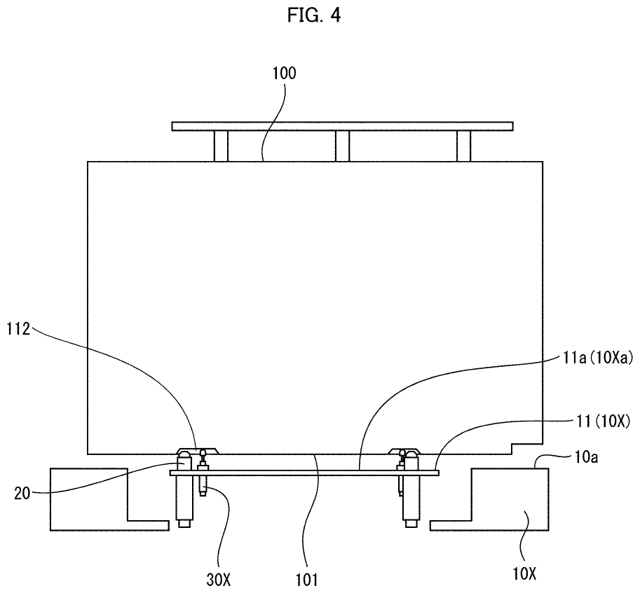

FIG. 4 is a cross-sectional view illustrating a placement base 10X in accordance with Embodiment 2 of the present invention and a storage container 100. As illustrated in FIG. 4, the placement base 10X differs from the placement base 10 in that the placement base 10X includes buffer bodies 30X instead of the buffer bodies 30. The other components of the placement base 10X are identical to those of the placement base 10.

### Buffer Bodies

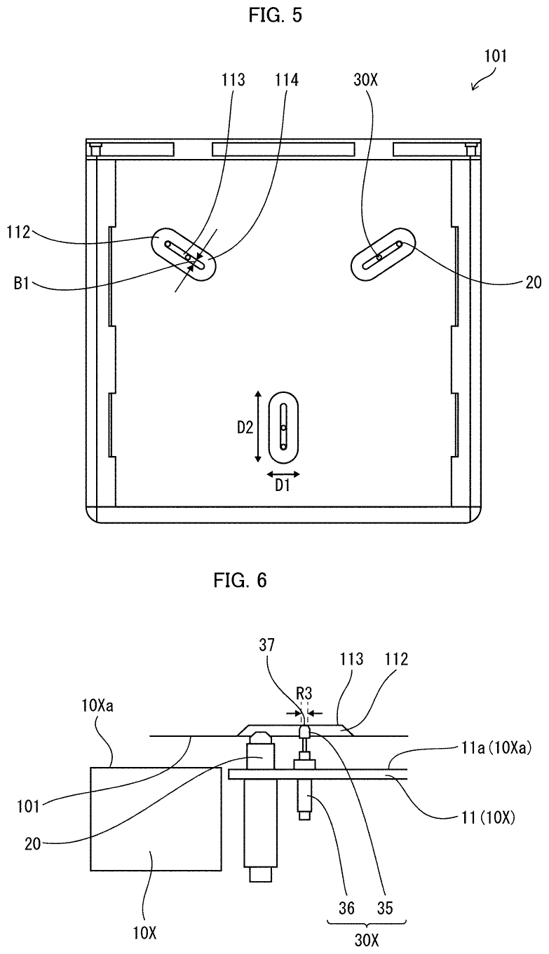

FIG. 5 is a view illustrating the bottom surface 101 of the storage container 100. FIG. 5 also illustrates, with solid lines, positions at which positioning pins 20 and the buffer bodies 30X abut on the bottom surface 101. FIG. 6 is a view illustrating each of the buffer bodies 30X and each of the positioning pins 20 during placement of the storage container 100 on the placement base 10X and illustrates the buffer body 30X and the positioning pin 20 at the time point of a start of contact of the buffer body 30X with the bottom surface 101 of the storage container 100.

As illustrated in FIG. 5, the buffer bodies 30X are provided on a top surface 10Xa of the placement base 10X so that, when the storage container 100 is placed on the placement base 10x, the buffer bodies 30X are to be located at positions which are inside the positioning grooves 112 on the bottom surface 101 of the storage container 100 and which are at substantially center parts of the positioning grooves 112 in width directions D1 of the positioning grooves 112. In addition, the buffer bodies 30X are provided on the top surface 10Xa so that, when the storage container 100 is placed on the placement base 10x, the buffer bodies 30X are to be located at positions which are inside the positioning grooves 112 on the bottom surface 101 of the storage container 100 and which are at substantially center parts of the positioning grooves 112 in length directions D2 of the positioning grooves 112. In a state where the storage container 100 is placed on the placement base 10X, a flat part 37 of the upper end of each of the buffer bodies 30X abuts on the flat part 113.

The buffer bodies 30X are, while the upper ends are not being pressed downward, located at a height at which the buffer bodies 30X come into contact, before the positioning pins 20, with the bottom surface 101 of the storage container 100. Thus, as illustrated in FIG. 6, even when the storage container 100 is lowered from a position above the placement base 10X, and the buffer body 30X comes into contact with the bottom surface 101 of the storage container 100, the positioning pin 20 does not come into contact with the bottom surface 101 (positioning groove 112). The storage container 100 is further lowered in this state, and then the upper end parts of the buffer bodies 30X are pressed downward and the positioning pins 20 come into contact with the flat parts 113, so that the storage container 100 becomes stationary. As a result, the storage container 100 is placed on the placement base 10X.

The buffer body 30X has a portion to come into contact with at least the bottom surface 101 of the storage container 100 (flat part 37). The portion has a columnar shape with a diameter smaller than a width B1 of the flat part 113. The following provides a specific description. In a state in which the storage container 100 is placed on the placement base 10x, the portion of the buffer body 30X which comes into contact with the positioning groove 112 (bottom surface) is only the flat part 37 of the upper end of the buffer body 30X. Assuming that the diameter of the flat part 37 of the upper end of the buffer body 30X in a state in which the storage container 100 is placed on the placement base 10X is “R3”, B1 is larger than R3 (see FIGS. 5 and 6). This makes it possible to suppress, in a manner so as to cause no effect on the positioning function for the storage container 100, swing of the storage container 100 which occurs when the storage container 100 is placed on the placement base 10X.

Each of the buffer bodies 30X includes a movable part 35 biased upward by a spring. The movable part 35 is fixed to the plate 11 via a support part 36. The buffer body 30X is, for example, a shock absorber using a spring.

This allows the buffer bodies 30X to absorb, in the positioning grooves 112, the impact of the storage container 100 which is generated when the storage container 100 is placed on the placement base 10X. This makes it possible to reduce a distance of relative movement of the storage container 100 and each of positioning pins 20 which occurs when the storage container 100 is placed on the placement base 10X. Therefore, it is possible to suppress the occurrence of wear between the positioning pins 20 and the storage container 100.

Each of the buffer bodies 30X has elasticity lower than that of each of the buffer bodies 30 and thus hardly bears the load of the storage container 100 in a state in which the storage container 100 is placed on the placement base 10X. Therefore, even if the buffer bodies 30X come into contact with the storage container 100 in the positioning grooves 112, the buffer bodies 30X have no effect on the positioning of the storage container 100 relative to the placement base 10X.

The positioning pins 20 and the buffer bodies 30X are fixed to the plate 11. Although not illustrated, each of the buffer bodies 30X may further include, below the movable part 35 thereof, a length adjusting mechanism which is, for example, a screw that adjusts a length by which the buffer body 30X protrudes upward from the top surface 10Xa.

Aspects of the present invention can also be expressed as follows:

A placement base (10·10X) in accordance with Aspect 1 of the present invention is a placement base on which a storage container (100) provided with a plurality of positioning grooves (112) on a bottom surface (101) of the storage container (100) is to be placed, the placement base (10·10X) including: a plurality of positioning pins (20) protruding upward from a top surface (10a·10Xa) of the placement base (10·10X), on which top surface the storage container (100) is to be placed; and a plurality of buffer bodies (30·30X) protruding upward from the top surface (10a·10Xa) of the placement base (10·10X), each of the plurality of positioning pins (20) being provided on the top surface (10a·10Xa) of the placement base (10·10X) in a manner so as to be engaged with a corresponding one of the positioning grooves (112), at least one of the plurality of buffer bodies (30·30X) being provided for each of the plurality of the positioning pins (20), the plurality of the buffer bodies (30·30X) having upper ends that are able to be pressed downward and that are configured to be biased upward when the upper ends are pressed down, the plurality of buffer bodies (30·30X), while the upper ends are not being pressed downward, being located at a height at which the plurality of buffer bodies (30·30X) come into contact, before the plurality of positioning pins (20), with the bottom surface (101) of the storage container (100) to be placed.

According to the above configuration, the buffer bodies come into contact with the bottom surface of the storage container, before the positioning pins come into contact with the storage container. This makes it possible to cause the buffer bodies to bear or absorb a load or an impact of the storage container which occur when the storage container is placed on the placement base. Therefore, even if the load of the storage container is large, it is possible to suppress occurrence of wear between the positioning pins and the storage container. Thus, it is possible to suppress the generation of particles during positioning even in a case where the load of the storage container is increased.

A placement base (10) in accordance with Aspect 2 of the present invention may be configured, in Aspect 1, such that the plurality of buffer bodies (30) each have an elastic parts (31) made of an elastic material; and the plurality of buffer bodies (30) are provided on the top surface (10a) of the placement base (10) so as to correspond to positions in the bottom surface (101) of the storage container (100), other than positions of the plurality of positioning grooves (112).

According to the above configuration, the buffer bodies are provided on the top surface of the placement base so as to correspond to positions other than the positions of the positioning grooves. Therefore, it is possible to provide the buffer bodies in a manner so as to cause no effect on the positioning function for the storage container. In addition, it is possible to determine the sizes of the buffer bodies irrespective of the sizes of the positioning grooves. Therefore, for example, increasing an area in which the buffer bodies come into contact with the bottom surface when the storage container is placed on the placement base makes it possible to increase a load of the storage container which the buffer bodies bear. This makes it possible to handle a storage container having a larger load.

A placement base (10) in accordance with Aspect 3 of the present invention may be configured, in Aspect 2, such that the elastic part (31) includes an upper end part (33) of a corresponding one of the plurality of buffer bodies (30), and the upper end part (33) has a round shape in which an uppermost end of the upper end part (33) is a center part (34) of the corresponding one of the plurality of buffer bodies (30).

According to the above configuration, the upper end parts of the buffer bodies are the elastic parts. When the storage container is placed on the placement base, the elastic parts are deformed. This makes it possible to place the storage container on the placement base with use of the positioning pins while causing the buffer bodies to absorb the load of the storage container.

Further, each of the buffer bodies has the upper end part having a round shape and thus evenly receives a load of the storage container. This makes it possible to prevent each of the buffer bodies from wearing out unevenly.

A placement base (10) in accordance with Aspect 4 of the present invention may be configured, in Aspect 2 or 3, such that the plurality of buffer bodies (30) each have a columnar shape with a diameter larger than that of each of the plurality of positioning pins (20).

According to the above configuration, the diameter of each of the buffer bodies is larger than that of each of the positioning pins, and thus it is possible to cause the buffer bodies to bear a larger proportion of the load of the storage container than that which the positioning pins bear. This makes it possible to further suppress the occurrence of wear between the positioning pins and the storage container.

A placement base (10) in accordance with Aspect 5 of the present invention may be configured, in any one of Aspects 2 to 4, such that, on the top surface (10a) of the placement base (10), the plurality of positioning pins (20) are provided at respective vertices of a first imaginary triangle (T1), and on the top surface (10a) of the placement base (10), the plurality of buffer bodies (30) are provided at respective vertices of a second imaginary triangle (T2) that encompasses the first imaginary triangle (T1) and that is made by enlarging the first imaginary triangle (T1).

According to the above configuration, it is possible to provide the buffer bodies evenly on the bottom surface of the storage container. This makes it possible to further suppress the occurrence of wear between the positioning pins and the storage container.

A placement base (10) in accordance with Aspect 6 of the present invention may be configured, in any one of Aspects 2 to 5, to further include a plate (11) having a top surface (11a) which is a part of the top surface (10a) of the placement base (10), the plurality of positioning pins (20) being fixed to the plate (11), the plurality of buffer bodies (30) being fixed to portions of the placement base (10), other than where the plate (11) is.

According to the above configuration, it is possible to precisely provide the positioning pins. In addition, disposing the buffer bodies at positions in the placement base other than the position of the plate makes it possible to cause the buffer bodies to be strongly held. This allows the buffer bodies to bear a larger load.

A placement base (10X) in accordance with Aspect 7 of the present invention may be configured, in Aspect 1, such that the plurality of buffer bodies (30X) each include a movable part (35) that is biased upward by a spring, and the plurality of buffer bodies (30X) are provided on the top surface (10Xa) of the placement base (10X) so as to each correspond to a position which is inside a corresponding one of the plurality of positioning grooves (112) on the bottom surface (101) of the storage container (100) and which is at a center of the corresponding one of the plurality of positioning grooves (112) in a width direction (D1) of the corresponding one of the plurality of positioning grooves (112).

According to the above configuration, it is possible to cause the buffer bodies to absorb, in the positioning grooves, the impact of the storage container which is generated when the storage container is placed on the placement base. This makes it possible to reduce a distance of relative movement of the storage container and each of the positioning pins which occurs when the storage container is placed on the placement base.

A placement base (10X) in accordance with Aspect 8 of the present invention may be configured, in Aspect 7, such that a center part of each of the plurality of positioning grooves (112) in the width direction (D1) forms a flat part (113) parallel to a main surface of the bottom surface (101) of the storage container (100), and the plurality of buffer bodies (30X) each have a portion to come into contact with at least the bottom surface (101) of the storage container (100), the portion having a diameter smaller than a width (B1) of each of the flat parts (113).

According to the above configuration, each of the buffer bodies has a portion to come into contact with at least the bottom surface of the storage container, and the portion has a diameter smaller than the width of the flat part of each of the positioning grooves. Therefore, it is possible to suppress, in a manner so as to cause no effect on the positioning function for the storage container, swing of the storage container which occurs when the storage container is placed on the placement base.

A placement base (10X) in accordance with Aspect 9 of the present invention may be configured, in Aspect 7 or 8, to further include a plate (11) having a top surface (11a) which is a part of the top surface (10Xa) of the placement base (10X), the plurality of positioning pins (20) and the plurality of buffer bodies (30X) being fixed to the plate (11).

According to the above configuration, it is possible to precisely provide the positioning pins and the buffer bodies.

A placement base (10·10X) in accordance with Aspect 10 of the present invention may be configured, in any one of Aspects 1 to 9, such that the plurality of buffer bodies (30·30X) each include a length adjusting mechanism (32) that adjusts a length by which a corresponding one of the plurality of buffer bodies (30·30X) protrudes upward from the top surface (10a·10Xa) of the placement base (10·10X).

According to the above configuration, it is possible to adjust the lengths of the buffer bodies in an up-and-down direction. Therefore, for example, it is possible to adjust a proportion of the load of the storage container which the buffer bodies bear. Further, even if the elastic parts are deformed due to use of the buffer bodies, adjusting the lengths of the buffer bodies enables long-term use of the buffer bodies.

The present invention is not limited to the embodiments, but can be altered by a skilled person in the art within the scope of the claims. The present invention also encompasses, in its technical scope, any embodiment derived by combining technical means disclosed in differing embodiments.

### REFERENCE SIGNS LIST

10, 10X Placement base
10a, 10Xa Top surface of placement base
11 Plate
20 Positioning pin
113 Flat part of positioning groove
30, 30X Buffer body
31 Elastic part
32 Length adjusting mechanism
33 Upper end part of buffer body
34 Center part of buffer body
35 Movable part
100 Storage container
101 Bottom surface
112 Positioning groove
B1 Width of flat part of positioning groove
D1 Width direction of positioning groove
T1 First imaginary triangle
T2 Second imaginary triangle

1. A placement base on which a storage container provided with a plurality of positioning grooves on a bottom surface of the storage container is to be placed, the placement base comprising:
a plurality of positioning pins protruding upward from a top surface of the placement base, on which top surface the storage container is to be placed; and
a plurality of buffer bodies protruding upward from the top surface of the placement base,
each of the plurality of positioning pins being provided on the top surface of the placement base in a manner so as to be engaged with a corresponding one of the plurality of positioning grooves,
at least one of the plurality of buffer bodies being provided for each of the plurality of positioning pins,
the plurality of the buffer bodies having upper ends that are able to be pressed downward and that are configured to be biased upward when the upper ends are pressed down,
the plurality of buffer bodies, while the upper ends are not being pressed downward, being located at a height at which the plurality of buffer bodies come into contact, before the plurality of positioning pins, with the bottom surface of the storage container to be placed.

2. The placement base according to claim 1, wherein:
the plurality of buffer bodies each have an elastic part made of an elastic material; and
the plurality of buffer bodies are provided on the top surface of the placement base so as to correspond to positions in the bottom surface of the storage container, other than positions of the plurality of positioning grooves.

3. The placement base according to claim 2, wherein:
the elastic part includes an upper end part of a corresponding one of the plurality of buffer bodies; and
the upper end part has a round shape such that an uppermost end of the upper end part is a center part of the corresponding one of the plurality of buffer bodies.

4. The placement base according to claim 2, wherein the plurality of buffer bodies each have a columnar shape with a diameter larger than that of each of the plurality of positioning pins.

5. The placement base according to claim 2, wherein:
on the top surface of the placement base, the plurality of positioning pins are provided at respective vertices of a first imaginary triangle; and
on the top surface of the placement base, the plurality of buffer bodies are provided at respective vertices of a second imaginary triangle that encompasses the first imaginary triangle and that is made by enlarging the first imaginary triangle.

6. The placement base according to claim 2, further comprising a plate having a top surface which is a part of the top surface of the placement base,
the plurality of positioning pins being fixed to the plate,
the plurality of buffer bodies being fixed to portions of the placement base, other than where the plate is.

7. The placement base according to claim 1, wherein:
the plurality of buffer bodies each include a movable part that is biased upward by a spring; and
the plurality of buffer bodies are provided on the top surface of the placement base so as to each correspond to a position which is inside a corresponding one of the plurality of positioning grooves on the bottom surface of the storage container and which is at a center of the corresponding one of the plurality of positioning grooves in a width direction of the corresponding one of the plurality of positioning grooves.

8. The placement base according to claim 7, wherein:
a center part of each of the plurality of the positioning grooves in the width direction forms a flat part parallel to a main surface of the bottom surface of the storage container; and
the plurality of buffer bodies each have a portion to come into contact with at least the bottom surface of the storage container, the portion having a diameter smaller than a width of each of the flat parts.

9. The placement base according to claim 7, further comprising a plate having a top surface which is a part of the top surface of the placement base,
the plurality of positioning pins and the plurality of buffer bodies being fixed to the plate.

10. The placement base according to claim 1, wherein the plurality of buffer bodies each include a length adjusting mechanism that adjusts a length by which the plurality of buffer body protrudes upward from the top surface of the placement base.
